(19) United States
(12) Patent Application Publication
(10) Pub. No.: US 2026/0271446 A1
(43) Pub. Date: Sep. 10, 2026

(54) LIGHT-EMITTING DEVICE AND METHOD OF MANUFACTURING LIGHT-EMITTING DEVICE

(71) Applicant: NICHIA CORPORATION, Anan-shi (JP)

(72) Inventor: Takeshi KUSUSE, Tokushima-shi (JP)

(73) Assignee: NICHIA CORPORATION, Anan-shi (JP)

(21) Appl. No.: 19/630,375

(22) Filed: Mar. 26, 2026

Related U.S. Application Data
(63) Continuation of application No. PCT/JP2024/033889, filed on Sep. 24, 2024.

(30) Foreign Application Priority Data
Sep. 27, 2023 (JP) 2023-165985

(51) Int. Cl. H10H 20/856; H10H 20/01; H10H 20/831

(52) U.S. Cl. CPC H10H 20/856; H10H 20/0363; H10H 20/831

(57) ABSTRACT

A light-emitting device includes: a light-emitting element including a semiconductor structure having an electrode-forming surface opposite to a light-emitting surface, and an electrode disposed on the electrode-forming surface; and a light-reflective member covering a lateral surface of the semiconductor structure and a lateral surface of the electrode, in which the electrode has an exposed surface not covered with the light-reflective member, and the light-reflective member includes a first light-reflective portion covering the lateral surface of the semiconductor structure and including an inorganic material as a main material and a light-reflective material having a refractive index higher than that of the inorganic material, and a second light-reflective portion covering at least a part of the lateral surface of the electrode and including: the lower surface of the light-reflective member, the inorganic material, and a lower content of the light-reflective material than the first light-reflective portion or substantially no light-reflective material.

### CROSS REFERENCE TO RELATED APPLICATION

This application is a continuation application of International Application No. PCT/JP2024/033889, filed on Sep. 24, 2024, which claims priority to Japanese Patent Applications No. 2023-165985, filed on Sep. 27, 2023, the entire contents of which are hereby incorporated by reference.

### TECHNICAL FIELD

The present disclosure relates to a light-emitting device and a method of manufacturing a light-emitting device.

### Background Art

In recent years, a light source that uses a light-emitting element such as a light-emitting diode has been widely used. For example, Patent Document 1 discloses a light-emitting device in which at least a lateral surface of a light-emitting element is covered with a light-reflective covering member, and a phosphor layer is disposed on an upper surface of the light-emitting element.

### CITATION LIST

### Patent Literature

Patent Document 1: JP 2018-14480 A

### SUMMARY OF INVENTION

### Technical Problem

However, there is still room for improvement in the light-reflective covering member in order to improve the performance of the light-emitting device. For example, a covering member covering a light-emitting element generates heat when irradiated with light from the light-emitting element, and thus further improvement in heat dissipation has been desired.

Accordingly, an object of the present disclosure is to provide a light-emitting device including a light-reflective member having high heat dissipation, and a method of manufacturing the light-emitting device.

### Solution to Problem

A light-emitting device according to the present disclosure includes: a light-emitting element comprising a semiconductor structure having a light-emitting surface, an electrode-forming surface opposite to the light-emitting surface, and a lateral surface located between the light-emitting surface and the electrode-forming surface, and an electrode disposed on the electrode-forming surface; and a light-reflective member having a lower surface and covering the lateral surface of the semiconductor structure and a lateral surface of the electrode, in which the electrode has an exposed surface not covered with the light-reflective member, and the light-reflective member comprises a first light-reflective portion covering the lateral surface of the semiconductor structure, the first light-reflective portion comprising an inorganic material as a main material and a light-reflective material having a refractive index higher than that of the inorganic material, and a second light-reflective portion covering at least a part of the lateral surface of the electrode, the second light-reflective portion comprising: the lower surface of the light-reflective member, the inorganic material, and a lower content of the light-reflective material than the first light-reflective portion or substantially no light-reflective material.

A method of manufacturing a light-emitting device according to the present disclosure includes: providing a light-emitting element, the light-emitting element comprising a semiconductor structure having a light-emitting surface, an electrode-forming surface opposite to the light-emitting surface, and a lateral surface located between the light-emitting surface and the electrode-forming surface, and an electrode disposed on the electrode-forming surface; providing a light-reflective inorganic member, the light-reflective inorganic member comprising a first light-reflective portion made of an inorganic material comprising a light-reflective material, the first light-reflective portion having plasticity, and a second light-reflective portion made of an inorganic material comprising a lower content of light-reflective material than in the first light-reflective portion or substantially no light-reflective material, the second light-reflective portion having plasticity, the second light-reflective portion disposed below the first light-reflective portion; and depositing the electrode-forming surface of the light-emitting element such that the lateral surface and the electrode-forming surface of the semiconductor structure are covered with the first light-reflective portion by bringing the electrode into contact with the first light-reflective portion and pressing the electrode from a first light-reflective portion side of the light-reflective inorganic member.

### Advantageous Effects of Invention

According to the present disclosure, it is possible to provide a light-emitting device including a light-reflective member having high heat dissipation, and a method of manufacturing the light-emitting device.

### BRIEF DESCRIPTION OF DRAWINGS

FIG. 1 is a schematic cross-sectional view of a light-emitting device according to an embodiment of the present disclosure.

FIG. 2 is a schematic cross-sectional view of the light-emitting device according to a modification of an embodiment of the present disclosure.

FIG. 3 is an enlarged schematic cross-sectional view of a boundary portion between a first light-reflective portion and a second light-reflective portion in the light-emitting device according to the embodiment of the present disclosure.

FIG. 4 is a schematic cross-sectional view at a step in a method of manufacturing the light-emitting device of the present disclosure.

FIG. 5 is a schematic cross-sectional view at a step in the method of manufacturing the light-emitting device of the present disclosure.

FIG. 6 is a schematic cross-sectional view at a step in the method of manufacturing the light-emitting device of the present disclosure.

FIG. 7 is a schematic cross-sectional view at a step in the method of manufacturing the light-emitting device of the present disclosure.

FIG. 8 is a schematic cross-sectional view at a step in the method of manufacturing the light-emitting device of the present disclosure.

FIG. 9 is a schematic cross-sectional view at a step in the method of manufacturing the light-emitting device of the present disclosure.

FIG. 10 is a schematic cross-sectional view at a step in the method of manufacturing the light-emitting device of the present disclosure.

### DESCRIPTION OF EMBODIMENTS

Embodiments of the present disclosure are described below with reference to the drawings. The light-emitting device and the method of manufacturing the light-emitting device described below are intended to embody the technical idea of the present disclosure, and the present disclosure is not limited to the following description unless otherwise specified.

In each drawing, members having identical functions may be denoted by the same reference characters. For ease of explanation or understanding of the gist, the plurality of exemplary embodiments and examples may be illustrated separately for convenience, but partial substitutions or combinations of the constituent components illustrated in different embodiments and examples are possible. In the embodiments and examples described later, descriptions of matters that are the same as those in the embodiments and examples described earlier will be omitted, and only matters different from those will be described. In particular, similar effects of similar configurations will not be mentioned each time for individual embodiments. The sizes, positional relationship, and the like of members illustrated in the drawings may be exaggerated in order to clarify explanation. As a cross-sectional view, an end view illustrating only a cut surface may be used.

### Embodiment of Light-Emitting Device

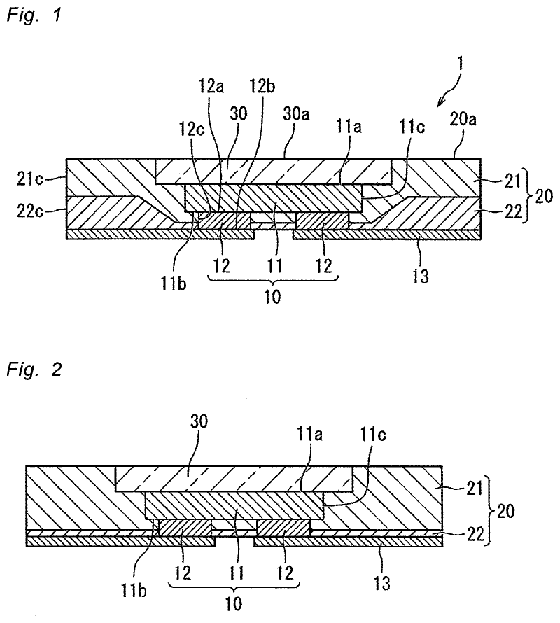

A light-emitting device 1 according to an embodiment of the present disclosure will be described in detail with reference to FIG. 1. The light-emitting device 1 according to an embodiment of the present disclosure includes at least a light-emitting element 10 and a light-reflective member 20.

The light-emitting element 10 includes a semiconductor structure 11 and a first electrode 12. The semiconductor structure 11 has a light-emitting surface 11a, an electrode-forming surface 11b opposite to the light-emitting surface 11a, and a lateral surface 11c located between the light-emitting surface 11a and the electrode-forming surface 11b. The first electrode 12 is disposed on the electrode-forming surface 11b, and has a first surface 12a facing the electrode-forming surface 11b, a second surface 12b located on a side opposite to the first surface 12a, and a lateral surface 12c located between the first surface 12a and the second surface 12b.

The light-reflective member 20 covers the light-emitting element 10 except for the light-emitting surface 11a and the second surface 12b. The light-reflective member 20 includes a first light-reflective portion 21 covering at least the lateral surface 11c of the semiconductor structure 11, and a second light-reflective portion 22 covering at least a part of the lateral surface 12c of the first electrode 12 at the second surface 12b side and a lower surface of the first light-reflective portion 21.

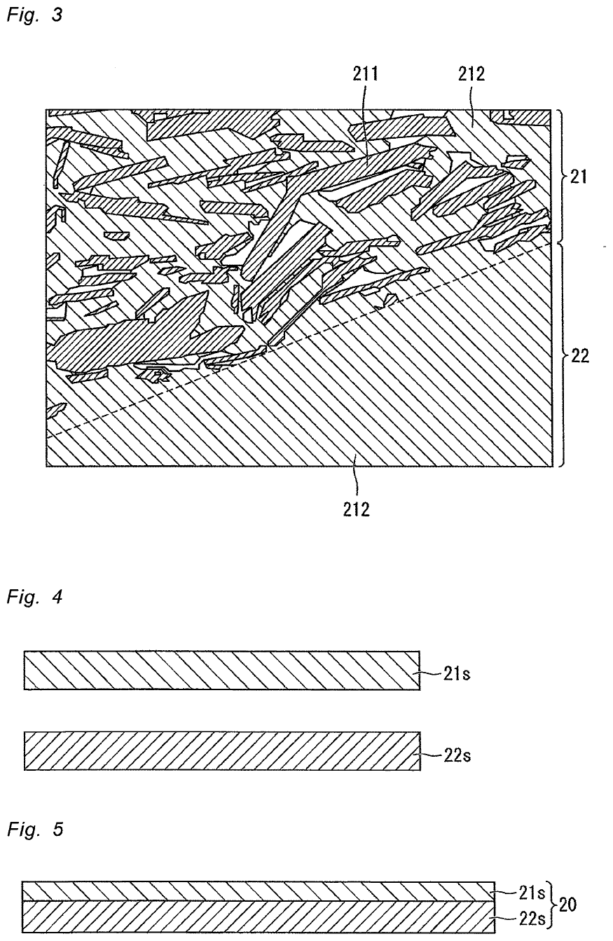

Hereinafter, components of the light-emitting device 1 according to the embodiment of the present disclosure will be described in detail with reference to FIGS. 1 and 3.

Although FIGS. 1 and 3 illustrate the components including a light-transmissive member 30 and a second electrode 13, the invention of the present disclosure may or may not include the light-transmissive member 30 and the second electrode 13. In the case in which the light-emitting device 1 includes the light-transmissive member 30, an upper surface 30a of the light-transmissive member 30 functions as a light-emitting surface of the light-emitting device 1.

### Light-Emitting Element

As the light-emitting element 10, for example, a semiconductor light-emitting element such as a light-emitting diode can be used, and the light-emitting element 10 configured to emit ultraviolet light or visible light of blue, green, red, or the like can be used. The light-emitting element 10 includes a semiconductor structure 11 including a light-emitting layer, and the first electrode 12. The semiconductor structure 11 has a surface on which the first electrode 12 is formed (electrode-forming surface) and a light-extracting surface (light-emitting surface) opposite to the electrode-forming surface.

The semiconductor structure 11 includes a semiconductor layer including a light-emitting layer. The semiconductor structure 11 may further include a light-transmissive substrate of sapphire or the like on the light-emitting surface 11a of the semiconductor structure 11. As an example, the semiconductor structure 11 may include three semiconductor layers of a first conductivity type semiconductor layer (for example, an n-type semiconductor layer), a light-emitting layer (an active layer), and a second conductivity type semiconductor layer (for example, a p-type semiconductor layer). The semiconductor layer configured to emit ultraviolet light or visible light from blue light to green light can be made of, for example, a semiconductor material such as a group III-V compound semiconductor. Specifically, a nitride-based semiconductor material such as In_{X}Al_{Y}Ga_{1-X-Y}N (0≤X, 0≤Y, X+Y≤1) can be used. As a semiconductor layer configured to emit red light, GaAs, GaAlAs, GaP, InGaAs, InGaAsP, or the like can be used. The peak wavelengths of the light emitted from the semiconductor structure 11 may be, for example, in a range from 260 nm to 630 nm.

The first electrode 12 includes, for example, a negative electrode and a positive electrode, and is disposed on the same surface side (electrode-forming surface) of the semiconductor structure 11. The first electrode 12 has the first surface 12a facing the electrode-forming surface 11b of the semiconductor structure 11, the second surface 12b opposite to the first surface 12a, and the lateral surface 12c located between the first surface 12a and the second surface 12b. Each of the negative electrode and the positive electrode included in the first electrode 12 may have a single-layer structure or a multilayered structure. This first electrode 12 can be formed to have any thickness, using a material and a configuration known in the art. For example, it is preferable for the thickness of the first electrode 12 to be in a range from ten and several μm to 300μm. In addition, as the first electrode 12, a good conductor can be used, and for example, a metal such as Cu is suitable. The shape of the electrode can be selected from among various shapes according to the purpose, application, and the like.

### Light-Reflective Member

The light-reflective member 20 covers the lateral surface 11c of the semiconductor structure 11 and the lateral surface 12c of the first electrode 12, and the second surface 12b of the first electrode 12 is exposed from a lower surface of the light-reflective member 20.

In the case in which the light-emitting device 1 includes the light-transmissive member 30, the light-reflective member 20 also covers, for example, a lateral surface of the light-transmissive member 30. In the present specification, the second surface 12b of the first electrode 12 is also referred to as an exposed surface.

In the light-emitting device 1 of the present embodiment, the light-reflective member 20 is made of an inorganic material, and can have a higher heat resistance than a light-reflective member made of a resin as a main component, and can be more reliable even when applied to a light-emitting device having high light emission intensity. In addition, deterioration of the inorganic material due to light is smaller than that of a resin, and in particular, even when the inorganic material is applied to a light-emitting device using the light-emitting element 10 that emits ultraviolet light having higher energy than visible light, deterioration of the inorganic material due to light can be inhibited. A peak wavelength of the light-emitting element 10 that emits ultraviolet light is, for example, 410 nm or less.

In addition, the inorganic material has a higher thermal conductivity than an organic material and has good heat dissipation characteristics. Thus, heat can be appropriately released toward the outside of the first light-reflective portion 21 (for example, toward the second light-reflective portion 22 or the light-transmissive member 30) and the heat dissipation can be improved.

In the light-emitting device 1 of the present embodiment, the lower surface of the light-reflective member 20 is a mounting surface side, and the second surface (exposed surface) 12b of the first electrode 12 exposed from the lower surface of the light-reflective member 20 is connected to an electrode of a mounting substrate, for example, directly or via the second electrode 13 that is an auxiliary electrode. In the light-emitting device 1, the mounting surface may be subjected to various processings during manufacturing as will be described for the manufacturing method to be described later, and also in the light-emitting device 1 after manufacturing, for example, force or heat is applied during mounting.

Accordingly, in the light-emitting device 1 of the present embodiment, the light-reflective member 20 includes the first light-reflective portion 21 located on the light-emitting surface 11a side and covering the lateral surface 11c of the semiconductor structure 11 and the lateral surface of the light-transmissive member 30 when the light-transmissive member 30 is included, and the second light-reflective portion 22 located on the mounting surface side. The lateral surface of the light-reflective member 20 includes a first lateral surface 21c of the first light-reflective portion 21 and a second lateral surface 22c of the second light-reflective portion 22 located below the first lateral surface 21c.

The first light-reflective portion 21 includes an inorganic material as a main material and a light-reflective material having a higher refractive index than the inorganic material. The second light-reflective portion 22 includes an inorganic material as a main material, and includes a lower content of light-reflective material than in the first light-reflective portion 21, or includes substantially no light-reflective material. The second light-reflective portion 22 may include, as the inorganic material as the main material, for example, the same inorganic material as the first light-reflective portion 21. The second light-reflective portion 22 is located on the mounting surface side to form the lower surface of the light-reflective member 20, and covers at least a part of the lateral surface 12c of the electrode 12.

Hereinafter, the first light-reflective portion 21 and the second light-reflective portion 22 will be described in more detail.

The first light-reflective portion 21 has a higher reflectance than the second light-reflective portion 22, and reflects the light emitted from the light-emitting element 10 more effectively than that. The first light-reflective portion 21 can reflect light from the light-emitting element 10 at a reflectance of 70% or more, for example. The first light-reflective portion 21 is a member made of an inorganic material as a main component. The first light-reflective portion 21 includes a light-reflective material (filler) of an inorganic material, and a support material made of an inorganic material and supporting the light-reflective material. The light-reflective material can improve the reflectance, and can also inhibit shrinkage due to, for example, heating during manufacturing, and inhibit the occurrence of cracks. In addition, after manufacturing, the light-reflective material functions as an aggregate that inhibits the occurrence of deformation and cracks due to heat. This function as an aggregate can be more effectively exhibited when the light-reflective material is, for example, plate-shaped or needle-shaped particles. Examples of the light-reflective material include at least one selected from boron nitride, silicon nitride, aluminum nitride, and aluminum oxide. Among these, boron nitride has high heat dissipation and can efficiently dissipate heat generated by the light-emitting element. Thus, the first light-reflective portion 21 includes the light-reflective material that can function as the aggregate, and thus, the light reflectance can be increased, and in addition, the quality of the first light-reflective portion 21 during and after manufacturing can be improved.

Hereinafter, the light-reflective material of the plate-shaped or needle-shaped particles will be specifically described with reference to FIG. 3.

FIG. 3 is a schematic cross-sectional view illustrating a part of the cross-section of the light-reflective member 20 in which the light-reflective material 211 made of boron nitride is contained in a support material 212 made of silicon oxide (silica). In FIG. 3, the first light-reflective portion 21 is above a broken line and the second light-reflective portion 22 is below the broken line. FIG. 3 illustrates an example in which the second light-reflective portion 22 includes substantially no light-reflective material 211.

The plate-shaped or needle-shaped light-reflective material 211 is not limited to boron nitride, and may be, for example, silicon nitride, aluminum nitride, or aluminum oxide. The light-reflective material 211 may be primary particles, or secondary particles in each of which two or more primary particles are aggregated. In addition, the light-reflective material 211 may be a mixture of the primary particles and the secondary particles.

The plate-like shape or needle-like shape of the light-reflective material 211 refers to a shape in which an average aspect ratio of the light-reflective material 211 in the cross-section of the first light-reflective portion 21 is 5 or more, and the average aspect ratio is preferably 10 or more, and more preferably in a range from 10 to 70. Using this plate-shaped or needle-shaped light-reflective material 211 can inhibit deformation of the first light-reflective portion 21 more effectively. The plate-shaped light-reflective material 211 includes a scale-shaped light-reflective material described later.

### Calculation Method of Average Aspect Ratio

The average aspect ratio of the light-reflective material 211 is calculated from the thickness and width of the light-reflective material 211 measured in a cross-section of the first light-reflective portion 21.

First, the light-emitting device is cut in a direction substantially perpendicular to the light-emitting surface to form the cross-section of the first light-reflective portion 21. Subsequently, the exposed cross-section is mirror polished. The mirror-polished cross-section is photographed with a scanning electron microscope (SEM). A measurement region including the cross-section of approximately 1000 pieces of the light-reflective material 211 is selected. In the example herein, the number of pixels of the microscope is set to approximately 20 megapixels, and the magnification is set to in a range of 500× to 3000×.

The plate-shaped or needle-shaped pieces of the light-reflective material 211 tend to be disposed to overlap each other due to their shapes in the first light-reflective portion 21.

Subsequently, using image analysis software, the width (the length in the longitudinal direction of the cross-section of the light-reflective material) at one location and the thickness (the length in the short-side direction of the cross-section of the light-reflective material) at one location are measured for each of the extracted cross-sections of the light-reflective material 211 to calculate the ratios of the widths relative to the thicknesses. Then, the average value of the calculated values of the measured light-reflective material 211 is set as the average aspect ratio.

A mean particle diameter of the light-reflective material 211 is preferably in a range from 0.6 μm to 43 μm, and more preferably in a range from 2 μm to 20 μm. In a case in which the light-reflective material 211 is boron nitride, the mean particle diameter of the light-reflective material 211 is in a range from 6 μm to 43 μm, for example. In a case in which the light-reflective material 211 is aluminum oxide, the mean particle diameter of the light-reflective material 211 is in a range from 0.6 μm to 10 μm, for example.

The mean particle diameter of the light-reflective material 211 can be calculated in the following manner.

The particle diameter of the light-reflective material 211 calculated by the method for calculating the mean particle diameter described below is a particle diameter of a powder used as a raw material of the light-reflective material 211 when forming the first light-reflective portion 21, but a particle diameter of the raw material of the light-reflective material 211 is not substantially different from the particle diameter of the light-reflective material 211 included in the first light-reflective portion 21 after its formation.

The mean particle diameter of the light-reflective material 211 included in the first light-reflective portion 21 can be measured by the following method.

### Calculation Method of Mean Particle Diameter

The particle diameter of the powder of the light-reflective material 211 is calculated by using, for example, a scanning electron microscope “TM3030Plus” manufactured by Hitachi High-Tech Corporation.

First, one surface of a double-sided tape made of carbon is attached to a sample stage of the microscope, and thereafter the powder of the light-reflective material 211 is disposed on the other surface of the double-sided tape. The number of pixels of the microscope is set to 1.23 megapixels, and the magnification is set in a range of 1000× to 2000× to acquire the image of 100 pieces (particles) of the powder of the light-reflective material 211. Thereafter, the particle diameter of each particle is measured using image analysis software. In the present description, the particle diameter of the powder of the light-reflective material 211 is a maximum diameter of the main surface of the light-reflective material 211. Subsequently, the median diameter of the measured particles is calculated, and the calculated value is set as the mean particle diameter of the light-reflective material 211. In addition, the particle diameter of the powder of the light-reflective material 211 may be calculated from the cross-section of the first light-reflective portion 21 measured with the image analysis software by using the SEM.

In the first light-reflective portion 21, the light-reflective material is supported by the support material made of the inorganic material, and thus the first light-reflective portion 21 can be formed into a desired shape. Examples of the support material include an inorganic polymer in which potassium hydroxide is mixed with at least one selected from aluminum oxide, calcium oxide, and silicon oxide. For the potassium hydroxide, an aqueous solution of potassium hydroxide is mixed into the support material, and evaporation of moisture in the aqueous solution causes formation of voids dispersed inside the first light-reflective portion 21. This can inhibit shrinkage during the formation of the first light-reflective portion 21. Here, it is preferable that the light-reflective material 211 and the support material are contained such that the volume of the light-reflective material 211 is in a range of 0.5 times to 5 times the volume of the support material. Within this range, shrinkage of the mixture during curing can be reduced. Further, the mean particle diameter of the support material is preferably smaller than the mean particle diameter of the light-reflective material 211. With such a particle size, voids formed between the fillers at the time of mixing can be filled with the support material. The mean particle diameter of the support material can be calculated by measuring the particle size distribution by a laser diffraction method.

The light-reflective material 211 and the support material described above are mixed with, for example, an alkali solution containing an alkali metal, and are obtained through steps such as heating. That is, the first light-reflective portion 21 may include an alkali metal derived from the alkaline solution. Examples of the alkali metal included in the alkaline solution include potassium and/or sodium. When the light-reflective material 211 and the support material are mixed with the alkaline solution, the light-reflective material 211 can be appropriately dispersed in the first light-reflective portion 21.

The first light-reflective portion 21 may further include a light-scattering material. The light-scattering material is, for example, mainly zirconium oxide or titanium oxide. In the case in which the light-emitting element emits ultraviolet light, zirconium oxide, which absorbs less light in the ultraviolet wavelength region, is desirable. When the first light-reflective portion 21 includes the light-scattering material, the light reflectance of the first light-reflective portion 21 is improved. This results in a sharp difference in luminance between the light-emitting surface of the light-emitting device 1 and an upper surface 20a (non-light-emitting surface) of the light-reflective member 20 surrounding the light-emitting surface in a top view. That is, the visibility on the light-emitting surface side of the light-emitting device 1 can be improved. As the light-scattering material, titanium oxide alone may be used, or titanium oxide whose surface is covered with a coating film formed of one or more of silica, aluminum oxide, zirconium oxide, zinc, an organic material, and the like may be used. As the light-scattering material, zirconium oxide alone may be used, or zirconium oxide whose surface is covered with a coating film formed of one or more of silica, aluminum oxide, zinc, an organic material, and the like may be used. Alternatively, stabilized zirconium oxide to which calcium, magnesium, yttrium, aluminum, or the like is added, or partially stabilized zirconium oxide may be used.

As described above, the second light-reflective portion 22 includes an inorganic material, and includes a lower content of light-reflective material than in the first light-reflective portion 21, or includes substantially no light-reflective material. The second light-reflective portion 22 is disposed on the mounting surface side of the light-emitting device. Thus, the quality of the mounting surface side can be improved as compared to the case in which the lower surface of the first light-reflective portion 21 is the mounting surface of the light-emitting device. As described above, the light-reflective material 211 included in the first light-reflective portion 21 improves the reflectance and functions as the aggregate. However, the present inventors have found that when the content of the light-reflective material is increased to have a desired reflectance, additional problems occur on the mounting surface side. One problem is that, if the content of the light-reflective material (aggregate) increases, there is a tendency that elastic deformation less easily occurs, and chipping or cracking may occur when grinding is performed at the mounting surface side during manufacturing. Another problem is that, when the second electrode that is the auxiliary electrode is formed, sufficient adhesion to the second electrode may not be obtained.

Accordingly, in the present embodiment, the second light-reflective portion 22 including the inorganic material, and including a lower content of light-reflective material than in the first light-reflective portion 21, or including substantially no light-reflective material, is disposed on the mounting surface side of the light-emitting device.

Thus, the additional problems that occur on the mounting surface side when the light-reflective member 20 is made of the inorganic material can be solved.

The second light-reflective portion 22 can be formed using the support material made of the inorganic material exemplified for the first light-reflective portion 21, and the light-reflective material 211 made of the inorganic material exemplified for the first light-reflective portion 21.

The support material and the light-reflective material of the second light-reflective portion 22 may be the same as or different from the first light-reflective portion 21.

However, the support material of the first light-reflective portion 21 and the support material of the second light-reflective portion 22 are preferably the same inorganic material. Thus, a bonding strength at an interface between the second light-reflective portion 22 and the first light-reflective portion 21 can be increased.

In addition, an inorganic material that can effectively exhibit the function as the aggregate is selected for the light-reflective material 211 contained in the first light-reflective portion 21, while an inorganic material that can improve the quality on the mounting surface side as compared with the first light-reflective portion 21 is selected for the light-reflective material 211 contained in the second light-reflective portion 22. This allows the selected inorganic materials to effectively exhibit the functions required for the respective light-reflective portions. For example, the plate-shaped or needle-shaped inorganic material that can effectively exhibit the function as the aggregate is selected as the light-reflective material 211 contained in the first light-reflective portion 21, while a spherical-shaped inorganic material that has a low function as the aggregate is selected as the light-reflective material contained in the second light-reflective portion 22. This allows the selected inorganic materials to effectively exhibit the functions required for the respective reflective portions.

The second light-reflective portion 22 may further include the light-scattering material similarly to the first light-reflective portion 21. As the light-scattering material, a light-scattering material that is the same as or similar to that exemplified for the first light-reflective portion 21 can be used.

### Light-Transmissive Member

In the light-emitting device 1, the light-transmissive member 30 may be disposed on the light-emitting surface 11a of the light-emitting element 10. The light-transmissive member 30 may be, for example, a molded body of a resin material, ceramics, or glass.

The resin material of the light-transmissive member 30 is preferably a light-transmissive resin. Examples of the resin material of the light-transmissive resin include a thermosetting resin such as a silicone resin, a silicone modified resin, an epoxy resin, or a phenol resin, and a thermoplastic resin such as a polycarbonate resin, an acrylic resin, a methylpentene resin, or a polynorbornene resin. In particular, a silicone resin having good light resistance and heat resistance is suitable.

The light-transmissive member 30 may include a light diffusion member that diffuses light from the light-emitting element 10. The light diffusion member may include, for example, titanium oxide, barium titanate, aluminum oxide, or silicon oxide.

In the light-emitting device 1, the light-transmissive member 30 need not be disposed on the light-emitting surface 11a of the light-emitting element 10. In this case, the upper surface of the first light-reflective portion 21 and the light-emitting surface 11a of the light-emitting element 10 form the upper surface of the light-emitting device 1. The light-transmissive member 30 is not disposed on the light-emitting surface 11a of the light-emitting element 10, and thus the light-emitting device 1 can be miniaturized.

The light-transmissive member 30 may further include a wavelength conversion substance. As the wavelength conversion substance, an yttrium aluminum garnet-based phosphor (for example, (Y,Gd)₃(Al, Ga)₅O₁₂:Ce), a lutetium aluminum garnet-based phosphor (for example, Lu₃(Al,Ga)₅O₁₂:Ce), a terbium aluminum garnet-based phosphor (for example, Tb₃(Al,Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba,Sr,Ca,Mg)₂SiO₄:Eu), an oxynitride-based phosphor such as a β-SiAlON-based phosphor (for example, (Si,Al)₃(O,N)₄:Eu) or an α-SiAlON-based phosphor (for example, Ca(Si,Al)₁₂(O, N)₁₆:Eu), a nitride-based phosphor such as an LSN-based phosphor (for example, (La,Y)₃Si₆N₁₁:Ce), a BSESN-based phosphor (for example, (Ba,Sr)₂Si₅N₈:Eu), an SLA-based phosphor (for example, SrLiAl₃N₄:Eu), a CASN-based phosphor (for example, CaAlSiN₃:Eu), or an SCASN-based phosphor (for example, (Sr,Ca)AlSiN₃:Eu), a fluoride-based phosphor such as a KSF-based phosphor (for example, K₂SiF₆:Mn), a KSAF-based phosphor (for example, K₂(Si₁₋ₓAlₓ)F₆₋ₓ: Mn, where x satisfies 0<x<1), or an MGF-based phosphor (for example, 3.5MgO·0.5MgF₂·GeO₂:Mn), a quantum dot having a perovskite structure (for example, (Cs,FA,MA)(Pb,Sn)(F,Cl,Br,I)₃, where FA and MA represent formamidinium and methylammonium, respectively), a group II-VI quantum dot (for example, CdSe), a group III-V quantum dot (for example, InP), a quantum dot having a chalcopyrite structure (for example, (Ag,Cu)(In,Ga)(S,Se)₂), or the like can be used. Further, one type of these wavelength conversion substances can be used alone, or two or more types of these wavelength conversion substances can be used in combination.

Examples of the light-transmissive member 30 including the wavelength conversion substance include a member containing particles of the wavelength conversion substance described above in the resin material, ceramic, or glass, and a sintered body of the wavelength conversion substance described above. In addition, the light-transmissive member 30 may include a resin material containing particles of the wavelength conversion substance and disposed on one surface of a molded body of a resin material, ceramics, glass, or the like.

As illustrated in FIGS. 1, 3, and the like, the lateral surface of the light-transmissive member 30 is covered with, for example, the first light-reflective portion 21. Instead of being covered with the first light-reflective portion 21, the lateral surface of the light-transmissive member 30 may be, for example, flush with a lateral surface of the light-reflective member 20 to form an outer lateral surface of the light-emitting device 1.

### Second Electrode

The light-emitting device 1 may include the second electrode 13 bonded to the second surface 12b of the first electrode 12. The second electrode 13 may be provided to extend from the second surface 12b on the outer surface of the second light-reflective portion 22.

The second electrode 13 mainly functions as an external electrode of the light-emitting device 1. As the material of the second electrode 13, a material having better corrosion resistance and oxidation resistance than those of the first electrode 12 is preferably selected. For example, the outermost surface layer is preferably made of Au or a platinum group metal such as Pt. Considering that the light-emitting device 1 is mounted using solder, it is preferable to use Au, which has good solderability, for the outermost surface of the second electrode 13.

The second electrode 13 may be formed of only a single layer of a single material, or may be formed by layering layers of different materials. In particular, the second electrode 13 having a high melting point is preferably used, and examples thereof include Ru, Mo, Ta, and W. In addition, by providing such a metal having a high melting point between the first electrode 12 of the light-emitting element 10 and the outermost surface layer, a diffusion prevention layer that can reduce diffusion of Sn included in the solder to the first electrode 12 or to a layer close to the first electrode 12 can be formed. Examples of the layered structure having such a diffusion prevention layer include Ni/Ru/Au and Ti/Pt/Au. The thickness of the diffusion prevention layer (for example, Ru) is preferably in a range of about 10 Å to 1000 Å.

As described above, the light-emitting device 1 according to the embodiment of the present disclosure includes the light-reflective member 20, which can improve heat resistance characteristics. In addition, the light-emitting device 1 includes the second light-reflective portion 22, which can reduce deformation of the first light-reflective portion 21 due to processing during manufacture of the light-emitting device 1. As an example, in an “electrode exposing step” described below, the first light-reflective portion 21 is covered with the second light-reflective portion 22, and thus the influence of processing on the first light-reflective portion 21 can be reduced.

Next, a method of manufacturing the light-emitting device according to the embodiment of the present disclosure will be described.

A method of manufacturing the light-emitting device 1 according to the present disclosure includes the steps of: providing the light-emitting element 10, the light-emitting element 10 including the semiconductor structure 11 having the light-emitting surface 11a, the electrode-forming surface 11b opposite to the light-emitting surface 11a, and the lateral surface 11c located between the light-emitting surface 11a and the electrode-forming surface 11b, and the first electrode 12 provided on the electrode-forming surface 11b; providing the light-reflective member 20, the light-reflective member 20 including a first light-reflective portion 21s made of the inorganic material including the light-reflective material 211, the first light-reflective portion 21s having plasticity, and a second light-reflective portion 22s made of the inorganic material including a lower content of the light-reflective material 211 than in the first light-reflective portion 21s or including substantially no light-reflective material 211, the second light-reflective portion 22s having plasticity, the second light-reflective portion 22s being disposed below the first light-reflective portion 21s; and depositing the electrode-forming surface 11b of the light-emitting element 10 such that the lateral surface 11c and the electrode-forming surface 11b of the semiconductor structure 11 are covered with the first light-reflective portion 21s by bringing the electrode 12 into contact with the first light-reflective portion 21s and pressing the electrode 12 from a first light-reflective portion 21s side of the light-reflective member 20.

The method may further include a “step of providing and disposing the light-transmissive member 30”, a “step of exposing the first electrode 12”, and a “step of forming the second electrode 13”.

Either the “step of providing the light-emitting element 10” or the “step of providing the light-reflective member 20” may be performed earlier, or they may be performed in parallel.

The optional “step of disposing the light-transmissive member 30” is performed between the “step of providing the light-emitting element 10” and the “step of settling”, and the “step of exposing the first electrode 12” and the “step of forming the second electrode 13” are performed after the “step of settling”.

Hereinafter, the method of manufacturing the light-emitting device 1 according to the present disclosure will be described in detail including optional steps.

FIGS. 4 to 10 to be referenced in the following description illustrate the method of manufacturing the light-emitting device 1 including the optional steps.

### Step of Providing Light-Emitting Element 10

First, the light-emitting element 10 is provided, including the semiconductor structure 11 having the light-emitting surface 11a and the electrode-forming surface 11b opposite to the light-emitting surface 11a, and the first electrode 12 disposed on the electrode-forming surface 11b and having the first surface 12a facing the electrode-forming surface 11b, the second surface 12b located on the side opposite to the first surface 12a, and the lateral surface 12c located between the first surface 12a and the second surface 12b.

### Step of Providing and Disposing Light-Transmissive Member 30

In the case in which the light-emitting device 1 includes the light-transmissive member 30, the light-transmissive member 30 is provided, and the light-emitting element 10 is disposed on the light-transmissive member 30.

The light-transmissive member 30 contains a wavelength conversion substance such as a YAG phosphor, and may include the light diffusing member as described above. Examples of the light diffusion member include titanium oxide, barium titanate, aluminum oxide, and silicon oxide.

### Step of Providing Light-Reflective Member 20

The step of providing the light-reflective member 20 further includes the steps of: providing the first light-reflective portion 21s made of an inorganic material including the light-reflective material 211, the first light-reflective portion 21s having plasticity; providing the second light-reflective portion 22s made of an inorganic material including a lower content of the light-reflective material 211 than in the first light-reflective portion 21s or including substantially no light-reflective material 211, the second light-reflective portion 22s having plasticity; and providing the light-reflective member 20 in which the first light-reflective portion 21s and the second light-reflective portion 22s are layered by superimposing and pressing the first light-reflective portion 21s having plasticity and the second light-reflective portion 22s having plasticity.

Hereinafter, the step of providing the first light-reflective portion 21s, the step of providing the second light-reflective portion 22s, and the step of providing the light-reflective member 20 will be described below in order.

In the drawings, a sheet-shaped first light-reflective portion before being divided is denoted by the reference sign 21s, and a sheet-shaped second light-reflective portion before being divided is denoted by the reference sign 22s.

In the step of providing the first light-reflective portion 21s, first, the inorganic material as the main material (support material 212) and the light-reflective material 211 having a higher refractive index than the inorganic material are mixed with an alkaline solution to provide a first mixed material.

Subsequently, the first mixed material is pressed by, for example, a pressing process to provide the first light-reflective portion 21s having a predetermined thickness.

At this time, a mixing ratio of the inorganic material as the main material and the light-reflective material 211 to the alkaline solution in the step of providing the first mixed material, a pressing force, and the like in the pressing process in providing the first light-reflective portion 21s are set so that the first light-reflective portion 21s having a predetermined thickness is formed in consideration of deformation due to the pressing in the step of providing the light-reflective member 20 described later.

Further, in the step of providing the first mixed material, the mixing with the alkaline solution is performed, for example, using a stirring defoamer that can perform stirring under reduced pressure, to such an extent that a uniform viscosity is obtained.

In the step of providing the second light-reflective portion 22s, first, (i) only an inorganic material as the main material (the support material 212) or (ii) an inorganic material including the inorganic material as the main material (the support material 212) and a lower content of the light-reflective material 211 than in the first light-reflective portion 21s is mixed with the alkaline solution to provide a second mixed material.

Subsequently, the second mixed material is pressed by, for example, a pressing process to provide the second light-reflective portion 22s having a predetermined thickness.

Here, a mixing ratio of the inorganic material as the main material or the inorganic material including the inorganic material as the main material (support material 212) and the light-reflective material 211 to the alkaline solution in the step of providing the second mixed material, a pressing force, and the like in the pressing process in providing the second light-reflective portion 22s are appropriately set in consideration of deformation caused by the pressing in the step of providing the light-reflective member 20 described later so that the second light-reflective portion 22s having a predetermined thickness is formed.

In addition, the mixing with the alkaline solution in the step of providing the second mixed material is performed, for example, to such an extent that a uniform viscosity is obtained by, for example, a stirring defoamer that can perform stirring under reduced pressure.

In the step of providing the light-reflective member 20, as illustrated in FIG. 5, the light-reflective member 20 in which the first light-reflective portion 21s and the second light-reflective portion 22s are layered is produced by superimposing the first light-reflective portion 21s and the second light-reflective portion 22s and applying pressure to them by a pressing process or the like. The first light-reflective portion 21s includes a greater amount of the light-reflective material 211 (aggregates) than the second light-reflective portion 22s, and thus tends to have higher plasticity (fluidity), and as schematically illustrated in FIGS. 4 and 5, the first light-reflective portion 21s tends to be thinner than the second light-reflective portion 22s due to the application of pressure. The degree of plasticity (fluidity) is also an important parameter in the step of depositing the light-emitting element 10 into the light-reflective member 20 described below. Therefore, the plasticity of the first light-reflective portion 21s and the second light-reflective portion 22s, particularly the plasticity of the first light-reflective portion 21s, is preferably set also in consideration of the content of the light-reflective material 211.

### Step of Depositing Light-Emitting Element 10 into Light-Reflective Member 20

In the step of depositing the light-emitting element 10 into the light-reflective member 20, the electrode-forming surface 11b of the light-emitting element 10 is deposited into the light-reflective member 20 such that the lateral surface 11c and the electrode-forming surface 11b of the semiconductor structure 11 are covered with the first light-reflective portion 21s by bringing the electrode into contact with the first light-reflective portion 21s and pressing the electrode from the first light-reflective portion 21s side of the light-reflective member 20.

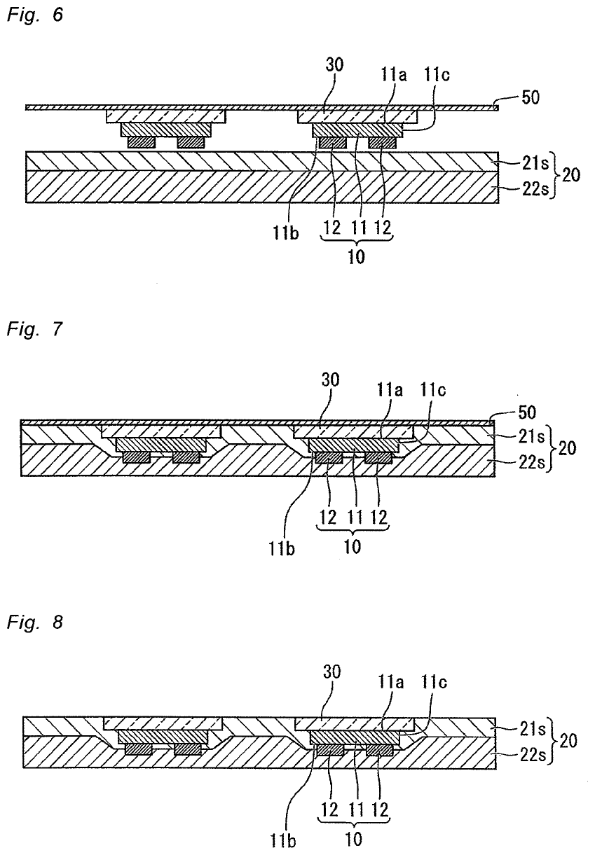

For example, as illustrated in FIG. 6, the light-emitting surface 11a of the light-emitting element 10, or the upper surface 30a of the light-transmissive member 30 when the light-emitting device 1 includes the light-transmissive member 30, is attached to one surface of the support plate 50, and the first electrode 12 of the light-emitting element 10 attached to the support plate 50 is brought into contact with the first light-reflective portion 21s from the first light-reflective portion 21s side and further pressed, and thus the light-emitting element 10 is deposited into the light-reflective member 20 as illustrated in FIG. 7. At this stage, both the first light-reflective portion 21s and the second light-reflective portion 22s are maintained in a state of having plasticity, and the electrode-forming surface 11b of the light-emitting element 10 and a part of the lateral surface 12c of the first electrode 12 of the light-emitting element 10 at the electrode-forming surface 11b side are covered with the first light-reflective portion 21s, and thus the second light-reflective portion 22s directly below the light-emitting element 10 and in the vicinity thereof becomes thin, while the second light-reflective portion 22s between the light-emitting element 10 and its adjacent light-emitting element 10 becomes thick. That is, at least a part of a boundary between the first light-reflective portion 21s and the second light-reflective portion 22s is inclined or curved toward the upper surface as the part of the boundary becomes increasingly further from the first electrode 12.

After the light-emitting element 10 is deposited into the light-reflective member 20, the light-reflective member 20 is heated to be cured.

As illustrated in FIG. 8, the support plate 50 is removed before or after the light-reflective member 20 is cured.

### Electrode Exposing Step

In the electrode exposing step, the second surface 12b of the first electrode 12 is exposed from the second light-reflective portion 22s by, for example, grinding the second light-reflective portion 22s.

### Second Electrode Forming Step

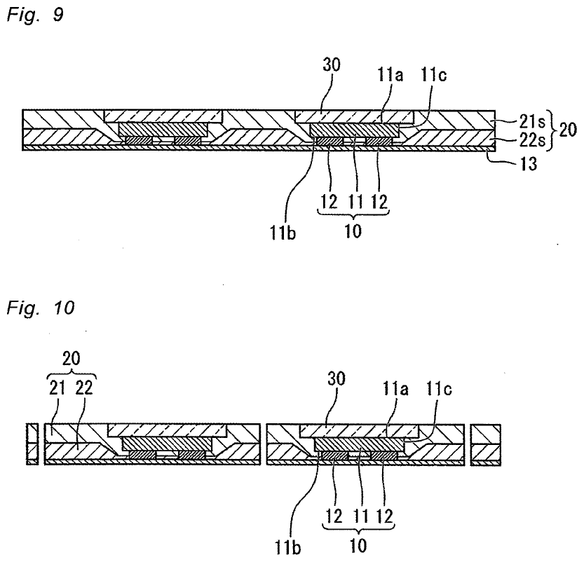

As illustrated in FIG. 9, in the second electrode forming step, the second electrode 13 is formed. The second electrode 13 is bonded to the second surface 12b of the first electrode 12 and extends from the second surface 12b on the outer surface of the second light-reflective portion 22s.

Because the second light-reflective portion 22s includes a low content of the light-reflective material 211 functioning as the aggregate or does not include the light-reflective material 211, the adhesion between the light-reflective member 20 and the second electrode 13 can be improved by forming the second electrode 13 on the outer surface of the second light-reflective portion 22s, and detachment of the second electrode 13 can be inhibited.

After the second electrode 13 is formed, singulation is performed by cutting at a predetermined cutting position.

Through the above steps, the light-emitting device 1 is manufactured.

In the light-emitting device 1 of the embodiment described above, the example is illustrated in which at least a part of the boundary between the first light-reflective portion 21s and the second light-reflective portion 22s is inclined toward the upper surface as the part of the boundary becomes increasingly further from the first electrode 12. However, the light-emitting device 1 according to the present disclosure is not limited thereto, and as illustrated in FIG. 2, the boundary between the first light-reflective portion 21 and the second light-reflective portion 22 may be, for example, parallel to the mounting surface.

### Example and Reference Example

In the example, the light-emitting device 1 illustrated in FIG. 1 was produced using the light-reflective member 20 including (a) the first light-reflective portion 21 made of a first mixed material obtained by providing a scale-shaped boron nitride (light-reflective material), silica (support material), and titania (light-scattering material) at a weight ratio of 2.5:2.5:1, and mixing them with an aqueous solution of potassium hydroxide (KOH) at a weight ratio of 6:2, and (b) the second light-reflective portion 22 made of a second mixed material obtained by providing a spherical-shaped aluminum oxide (light-reflective material), silica (support material), and titania (light-scattering material) at a weight ratio of 2:3.2:4, and mixing them with an aqueous solution of potassium hydroxide (KOH) at a weight ratio of 9.2:2.3.

In the example herein, as the light-emitting element 10, a light-emitting diode that emits light with a peak wavelength of 460 nm was used, and as the light-transmissive member, a material formed by mixing and sintering a YAG phosphor and aluminum oxide was used.

The second electrode 13 was formed on the surface of the second light-reflective portion 22 on the mounting surface side of the light-emitting device 1 produced as described above.

In contrast, as a reference example, a light-emitting device was produced in the same manner as in the example, except that the light-reflective member 20 was made only of the first light-reflective portion 21, and the second electrode 13 was formed on the surface of the first light-reflective portion 21 exposed on the mounting surface side.

The light-emitting device of the example obtained better adhesion than the light-emitting device of the reference example.

The embodiments disclosed this time are illustrative in all respects and are not intended to be the basis of limiting interpretation.

### REFERENCE NUMERALS LIST

1 Light-emitting device
10 Light-emitting element
11 Semiconductor structure
11a Light-emitting surface
11b Electrode-forming surface
11c Lateral surface
12 First electrode
12a First surface
12b Second surface
12c Lateral surface
13 Second electrode
20 Light-reflective member
21 First light-reflective portion
22 Second light-reflective portion
30 Light-transmissive member
50 Support plate

What is claimed is:

1. A light-emitting device comprising:
a light-emitting element comprising
a semiconductor structure having
a light-emitting surface,
an electrode-forming surface opposite to the light-emitting surface, and
a lateral surface located between the light-emitting surface and the electrode-forming surface, and
an electrode disposed on the electrode-forming surface; and
a light-reflective member having a lower surface and covering the lateral surface of the semiconductor structure and a lateral surface of the electrode,
wherein the electrode has an exposed surface not covered with the light-reflective member, and
wherein the light-reflective member comprises:
a first light-reflective portion covering the lateral surface of the semiconductor structure, the first light-reflective portion comprising an inorganic material as a main material and a light-reflective material having a refractive index higher than that of the inorganic material; and
a second light-reflective portion covering at least a part of the lateral surface of the electrode, the second light-reflective portion comprising the lower surface of the light-reflective member, the inorganic material, and a lower content of the light-reflective material than the first light-reflective portion or substantially no light-reflective material.

2. The light-emitting device according to claim 1, further comprising:
a light-transmissive member disposed on the light-emitting surface of the semiconductor structure, wherein
the first light-reflective portion further covers a lateral surface of the light-transmissive member.

3. The light-emitting device according to claim 1, wherein
the first light-reflective portion further covers a part of the lateral surface of the electrode.

4. The light-emitting device according to claim 1, wherein
at least a part of a boundary between the first light-reflective portion and the second light-reflective portion is inclined or curved toward an upper surface as the part of the boundary becomes increasingly further from the electrode.

5. The light-emitting device according to claim 1, wherein
a lateral surface of the light-reflective member comprises a first lateral surface of the first light-reflective portion, and a second lateral surface of the second light-reflective portion located below the first lateral surface.

6. The light-emitting device according to claim 1, wherein
an auxiliary electrode is disposed on a lower surface of at least a part of the light-reflective member and a lower surface of the electrode, and is electrically connected to the electrode.

7. The light-emitting device according to claim 1, wherein
the light-reflective material comprises at least one selected from boron nitride, silicon nitride, aluminum nitride, and aluminum oxide.

8. The light-emitting device according to claim 1, wherein
the light-reflective material comprises plate-shaped particles or needle-shaped particles.

9. The light-emitting device according to claim 1, wherein
the first light-reflective portion and the second light-reflective portion comprise an alkali metal.

10. A method of manufacturing a light-emitting device, the method comprising:
providing a light-emitting element, the light-emitting element comprising
a semiconductor structure having a light-emitting surface, an electrode-forming surface opposite to the light-emitting surface, and a lateral surface located between the light-emitting surface and the electrode-forming surface, and
an electrode disposed on the electrode-forming surface;
providing a light-reflective inorganic member, the light-reflective inorganic member comprising:
a first light-reflective portion made of an inorganic material comprising a light-reflective material, the first light-reflective portion having plasticity, and
a second light-reflective portion made of an inorganic material comprising a lower content of light-reflective material than the first light-reflective portion or substantially no light-reflective material, the second light-reflective portion having plasticity, the second light-reflective portion disposed below the first light-reflective portion; and
depositing the light-emitting element such that the lateral surface and the electrode-forming surface of the semiconductor structure are covered with the first light-reflective portion by bringing the electrode into contact with the first light-reflective portion and pressing the electrode from a first light-reflective portion side of the light-reflective inorganic member.

11. The method of manufacturing a light-emitting device according to claim 10, further comprising:
after the depositing of the light-emitting element, removing a part of the light-reflective inorganic member, into which the light-emitting element has been deposited, from a side of the second light-reflective portion, and exposing the electrode from the second light-reflective portion.

12. The light-emitting device according to claim 1, wherein
the first light-reflective portion or the second light-reflective portion comprises an alkali metal.
